(19) United States
(12) Patent Application Publication
(10) Pub. No.: US 2001/0000156 A1
(43) Pub. Date: Apr. 5, 2001

(54) Package board structure and manufacturing method thereof

(76) Inventor: David C. H. Cheng, Taoyuan Hsien (TW)

Correspondence Address: J.C. Patents, Suite 114, 1340 Reynolds Ave., Irvine, CA, 92614, US

(21) Appl. No.: 09/725,634

(22) Filed: Nov. 29, 2000

Related U.S. Application Data
(62) Division of application No. 09/325,364, filed on Jun. 4, 1999.

(51) Int. Cl. H01L 21/44

(52) U.S. Cl. 438/612; 438/613

(57) ABSTRACT

A method for forming package board for carrying a low pin count IC chip. A hard resin substrate board is provided. Through vias are formed in locations where ball grid pads are needed. A conductive layer that also covers the vias is attached to the surface of the board using a glue material. The conductive layer is patterned to form a conductive line layer. Ball grid pad regions on the conductive line layer are located above the vias. A soldering mask that covers a portion of the conductive line layer but exposes a plurality of bonding pad regions above the conductive line layer is formed. An electroplated layer is formed over the bonding pad regions.

### BACKGROUND OF THE INVENTION

1. 1. Field of Invention

2. The present invention relates to a package board structure and a manufacturing method thereof. More particularly, the present invention relates to a single-sided substrate board structure and a manufacturing method thereof.

3. 2. Description of Related Art

4. In the manufacturing of an integrated circuit (IC) product, the last manufacturing step is usually the formation of a package to enclose the IC chip. The package not only provide support to the IC chip on a printed circuit board (PCB), but also serves as a medium for electrical connection between various devices and mechanical protection for the chip.

5. Recently, the integration level of integrated circuits has been rapidly increasing, so most electronic products have become lighter and smaller. A host of packaging techniques including the so-called chip scale package (or chip size package) and multichip module package are currently employed. The development of such innovative packaging techniques demands an improved design for the chip carrier that supports the silicon chip. In addition, circuit layout of the circuit board for connecting electronic devices inside the package to external printed circuit board also needs some improvement.

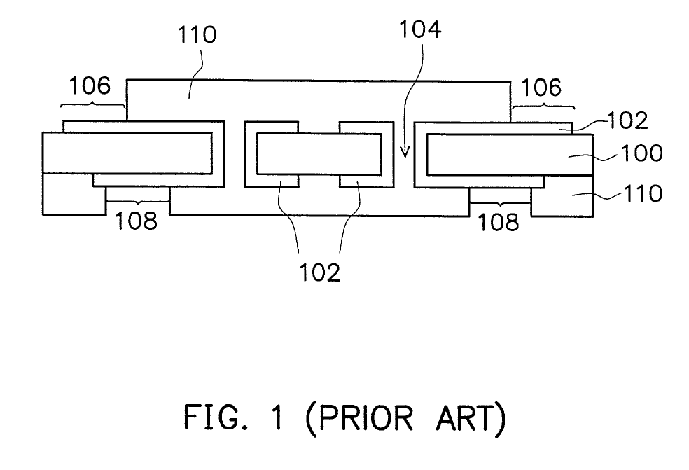

6. FIG. 1 is a schematic, schematic, cross-sectional diagram showing a conventional double-sided substrate board. The steps in manufacturing a double-sided substrate board include providing an epoxy substrate board 100, and punching through vias 104 in the board. An electroplating operation is carried out to form electroplated layers or conductive lines 102 over the board 100. The sidewalls of the vias 104 are also electroplated to form a connection from a conductive line 102 on one surface of the substrate board 100 to another conductive line 102 on a different surface. Soldering mask material is deposited to fill the vias 104 as well as to cover a portion of the substrate board 100 and a portion of the electroplated layer 102, thereby forming a solder mask (S/M) 110. The solder mask 110 exposes bonding pad regions 106 for bonding wires to corresponding pads on a silicon chip (not shown in the figure). The solder mask 110 also exposes ball pad regions 108 on the other side of the substrate board 100 for forming a ball grid array (BGA).

7. As shown in FIG. 1, bonding pads and ball pads on different surfaces of a conventional double-sided substrate board are connected electrically by the electroplated layer on the sidewalls of vias 104. The resulting circuit path is therefore extended. Hence, resistance-capacitance (RC) delay and other electrical properties may be affected.

8. At present, although chip scale package having a double-sided board or a laminated structure is widely used, a single-sided substrate board is often used in low pin count package. Typically, the single-sided substrate board is made of polyimide using tape as a chip carrier to form a tape ball grid array (TBGA). However, polyimide is a rather expensive material compared with other hard epoxy materials, and therefore may inflate the production cost.

### SUMMARY OF THE INVENTION

9. The invention provides a single-sided package board structure using hard resin as the board material. The package board is best suited for forming a low pin count package, and has a shorter circuit path and a reduced RC delay. Furthermore, the package is able to work faster and more efficiently at a lower production cost.

10. To achieve these and other advantages and in accordance with the purpose of the invention, as embodied and broadly described herein, the invention provides a method for forming package board for carrying a low pin count IC chip. A hard resin substrate board having an electroplated layer thereon is provided. Through vias are formed in locations where ball grid pads are needed, and the electroplated layer on the board surface are removed. A conductive layer is attached to the surface of the board using a glue material. The conductive layer also covers the through vias to form a plurality of openings. The conductive layer is patterned to form a conductive line layer. Ball grid pad regions on the conductive line layer are located at the bottom of the openings. A soldering mask that covers a portion of the conductive line layer but exposes a plurality of bonding pad regions of the conductive line layer is formed. An electroplated layer is formed over the bonding pad region.

11. The invention also provides a package board structure suitable for forming a low pin count package. The package board is formed using hard resin. The package board has a patterned conductive line layer over the board surface, and the conductive line has bonding pads above it. The conductive line layer also has bonding pad regions for electrical connection with a silicon chip. In addition, the conductive line layer also has a plurality of ball grid pads for forming a ball grid array. The hard resin board also has a number of openings that correspond in position to the ball grid pads. In fact, the ball grid pads are located on the conductive line layer at the bottom of the openings. There is also a solder mask above the conductive line layer. Whereas a portion of the conductive line layer is covered by the solder mask, the bonding pad regions of the conductive line layer are exposed. Furthermore, there is an electroplated layer over each bonding pad region.

12. It is to be understood that both the foregoing general description and the following detailed description are exemplary, and are intended to provide further explanation of the invention as claimed.

### BRIEF DESCRIPTION OF THE DRAWINGS

13. The accompanying drawings are included to provide a further understanding of the invention, and are incorporated in and constitute a part of this specification. The drawings illustrate embodiments of the invention and, together with the description, serve to explain the principles of the invention. In the drawings,

14. FIG. 1 is a schematic, cross-sectional diagram showing a conventional double-sided substrate board;

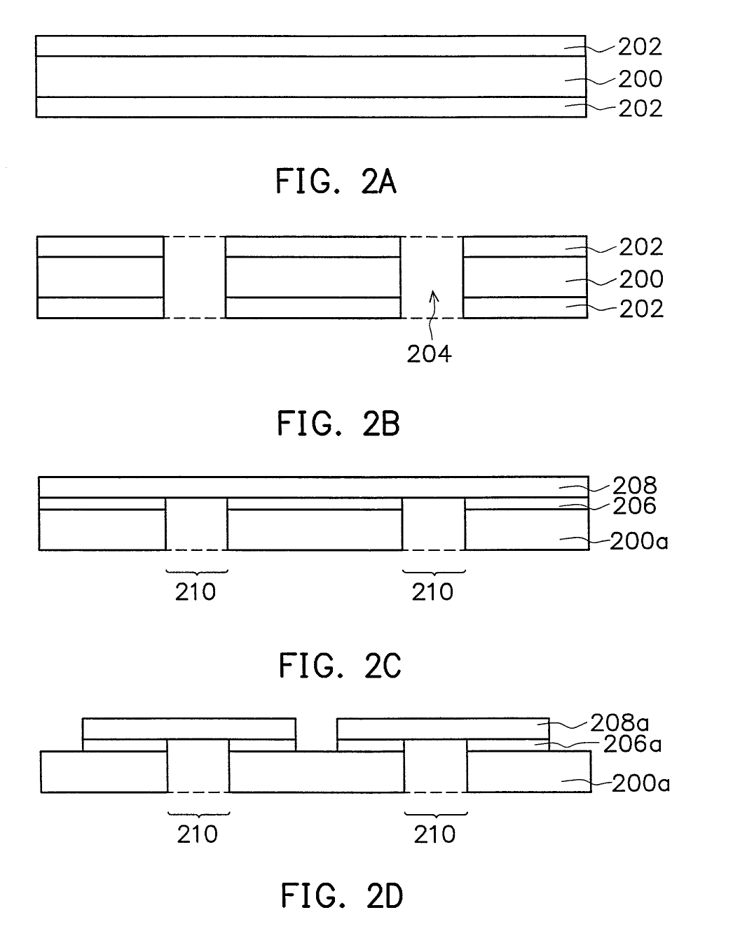

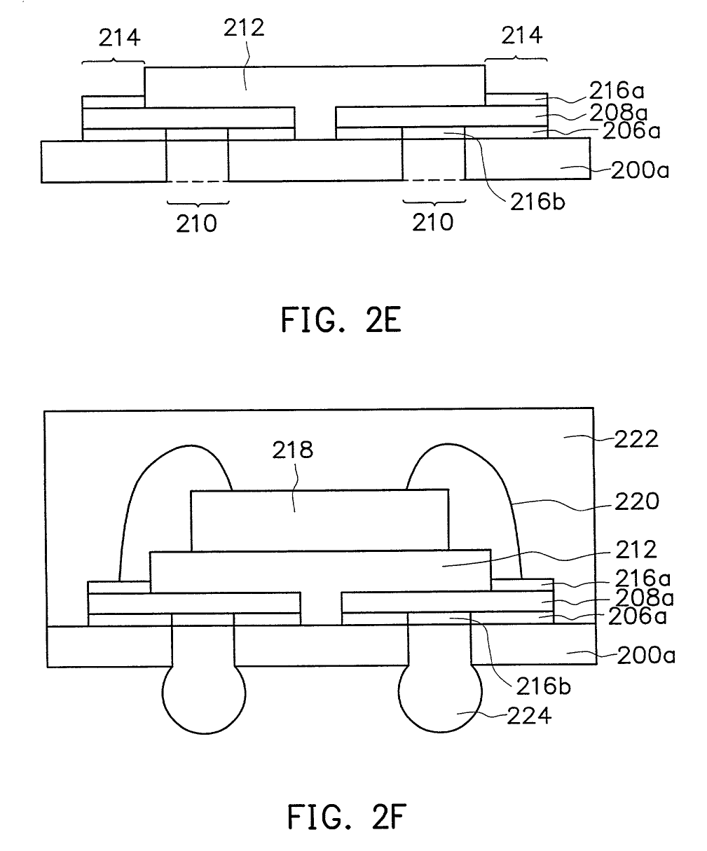

15. FIGS. 2A through 2F are schematic, cross-sectional views showing the progression of manufacturing steps for fabricating a substrate board together with the steps for forming a complete semiconductor package using the substrate board in a first embodiment of the invention; and

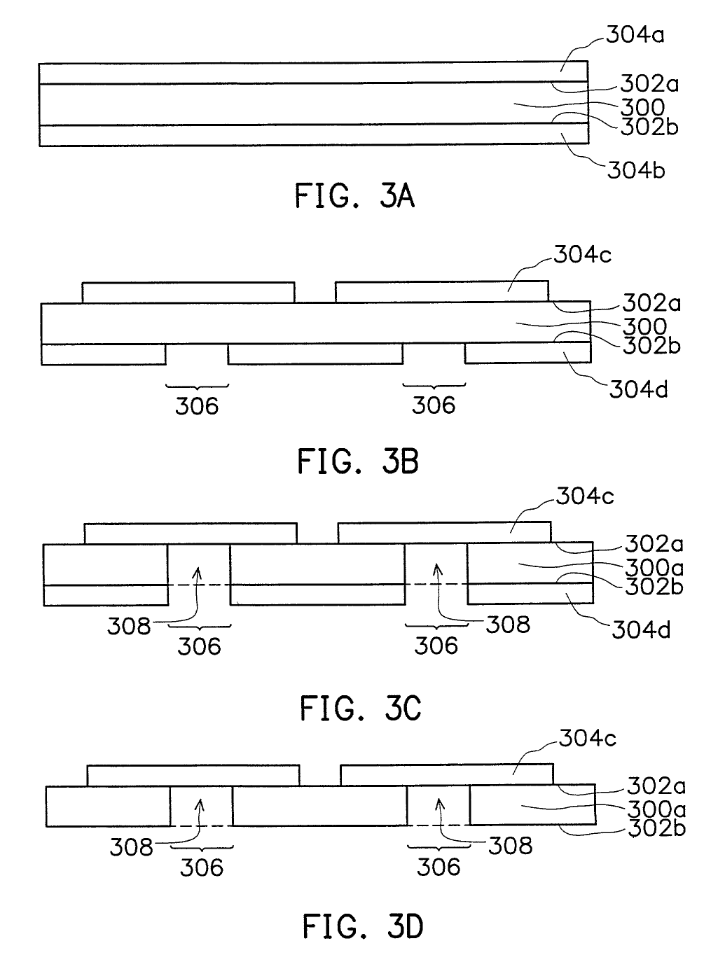

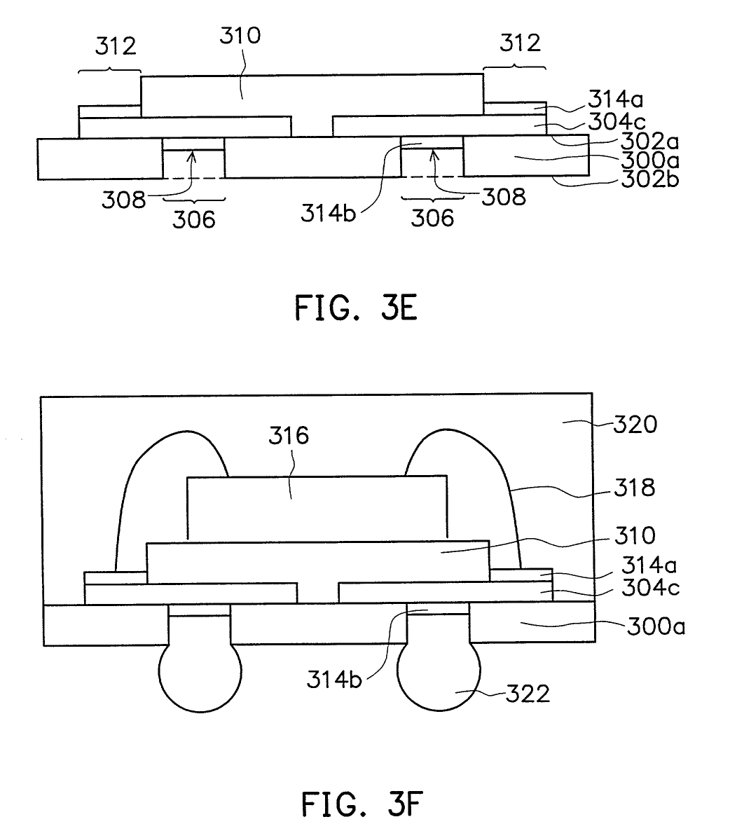

16. FIGS. 3A through 3F are schematic, cross-sectional views showing the progression of manufacturing steps for fabricating a substrate board together with the steps for forming a complete semiconductor package using the substrate board in a second embodiment of the invention.

### DESCRIPTION OF THE PREFERRED EMBODIMENTS

17. Reference will now be made in detail to the present preferred embodiments of the invention, examples of which are illustrated in the accompanying drawings. Wherever possible, the same reference numbers are used in the drawings and the description to refer to the same or like parts.

18. FIGS. 2A through 2F are schematic, cross-sectional views showing the progression of manufacturing steps for fabricating a substrate board together with the steps for forming a complete semiconductor package using the substrate board in a first embodiment of the invention.

19. As shown in FIG. 2A, a substrate board 200 having an electroplated layer 202 thereon is provided. The substrate board 200 is made from a hard resin material (Prepreg), which has a high glass transition temperature (Tg). Prepreg, for example, FR-4 board, FR-5 board and BT board, is made from material such as glass epoxy resin and bismaleimide-triazine (BT). The electroplated layer 202 is made from conductive material including copper.

20. As shown in FIG. 2B, through vias 204 having a diameter of about 2 mm are formed in the substrate board 200 at location where ball grid pads are required, and the substrate board 200 is transformed into a board 200a. A mechanical punching method, for example, can be used to form the vias 204.

21. As shown in FIG. 2C, the electroplated layer 202 above the board 200 is removed using, for example, a wet etching method. A glue layer 206 made from adhesive material is formed over the substrate board 200a, and a conductive layer 208 is attached to the substrate board 200a by means of the glue layer 206. The conductive layer 208 covers the through vias 204 as well. By forming vias 204 in the substrate board 200, the ball grid pad regions 210 on the conductive layer 208 are exposed. The glue layer 206 can be made from material including epoxy resin or BT, both of which are low fluidity resin. The conductive layer can be made from a conductive material such as copper.

22. As shown in FIG. 2D, the conductive layer 208 is patterned to form conductive line layers 208a according to a planned circuit layout. Hence, a portion of the substrate board 200a is exposed. The conductive line layers 208a can be formed by performing a photolithographic operation followed by etching using a wet etching method, for example.

23. As shown in FIG. 2E, a solder mask 212 is formed over the conductive line layers 208a so that a portion of the substrate board 200a and the conductive line layers are covered. Only regions above the conductive line layers 208a for forming bonding pad regions 214 are exposed. Electroplated layers are formed over the bonding pad region 214 to form electroplated bond pads 216a. Similarly, electroplated layers are formed over the ball grid pad regions 210 to form electroplated bond pads 216b. The processes necessary for forming a package board are now complete.

24. The soldering mask 212 in FIG. 2E is made from an insulation material such as an ultraviolet-sensitive compound or a bake-hardened compound. The solder mask material can be laid on top of the substrate board 202a by a roller coating method, a curtain coating method, a screen printing method or a dry film method. For example, the process of forming a soldering mask using an ultraviolet-sensitive compound includes coating the compound over the conductive line layers 208a. After the coated material is baked, exposed to light and developed, the coated material is baked a second time to form the solder mask 212. If, however, a thermal hardened type of material is used, the material is deposited over the conductive line layers 208a according to the desired solder mask pattern. The coated material is bake-hardened to form the solder mask 212.

25. The electroplated bond pads 216a and 216b in FIG. 2E can be formed by performing electroplating. The most commonly used materials for forming the electroplated layers includes gold (Au), silver (Ag), nickel (Ni), palladium (Pd), nickel—palladium alloy or a multi-layered composite containing various combinations of the elements above. The electroplated layers are preferably formed by electroplating a layer of nickel over the pad regions. A composite layer of nickel—palladium is next electroplated over the nickel layer. A layer of palladium is electroplated on top of the nickel—palladium layer. The nickel layer on the bottom is mainly used for preventing corrosion. The palladium layer on the top is able to improve bonding ability, molding compound characteristics and solderability of the bonding pad surface.

26. As shown in FIG. 2F, after the packaging board is made, a silicon chip 218 is placed on top of the solder mask 212 and is fixed in position using material such as an insulating plastic, silver paste or bonding tape. The silicon chip 218 and the conductive line layers 208a are electrically connected by performing a wire-bonding operation. Conductive wires 220 are used to link up bonding pads (not shown in the figure) on the silicon chip 218 with the electroplated bond pads 216a. The conductive wires 220, for example, are made of gold, aluminum or copper. A molding step is carried out using a packaging material 222 to enclose the silicon chip 218, the conductive wires 220, a portion of the soldering mask 212, the conductive line layers 208a and the substrate board 200a. The packaging material 222 includes resin and epoxy resin. Soldering material 224, including solder or copper balls, can also be placed over the electroplated layer 216b of the ball grid pads to form a ball grid array. The soldering material serves as a medium for connecting the chip package to a printed circuit board.

27. FIGS. 3A through 3F are schematic, cross-sectional views showing the progression of manufacturing steps for fabricating a substrate board together with the steps for forming a complete semiconductor package using the substrate board in a second embodiment of the invention.

28. As shown in FIG. 3A, a substrate board 300 having a first electroplated layer 304a on a first surface 302a of the board 300 and a second electroplated layer 304b on a second surface 302b of the board 300 is provided. The substrate board 300 is made from a hard resin material (Prepreg), which has a high glass transition temperature (Tg). Prepreg, for example, FR-4 board, FR-5 board and BT board, is made from material such as glass epoxy resin and bismaleimide-triazine (BT). The first electroplated layer 304a and the second electroplated layer 304b can be made from conductive material including copper.

29. As shown in FIG. 3B, the first electroplated layer 304a on the first surface 302a and the second electroplated layer 302b on the second surface 302b are patterned to form conductive line layers 304c and an intermediate electroplated layer 304d, respectively. The electroplated layers are patterned by performing a photolithographic operation followed by a wet etching operation. After the patterning step, the conductive line layers 304c contains the desired circuit pattern while the intermediate electroplated layer 304d contains a ball grid pad pattern for forming a ball grid array.

30. As shown in FIG. 3C, some substrate board material is removed to expose a portion of the conductive line layer 304c using the intermediate electroplated layer 304d as a mask. Consequently, a number of openings 308 in the substrate board 300a that leads to ball grid pad regions 306 are formed. The substrate board material can be removed using a laser ablation method, for example.

31. The intermediate electroplated layer 304d is removed, for example, by performing a wet etching operation as shown in FIG. 3D.

32. As shown in FIG. 3E, a solder mask 310 that covers a portion of the substrate 300a and the conductive line layers 304c is formed. Only regions above the conductive line layers 304c for forming bonding pad regions 312 are exposed. Electroplated layers are formed over the bonding pad regions 312 to form electroplated bond pads 314a. Similarly, electroplated layers are formed over the ball grid pad regions 306 to form electroplated bond pads 314b. The processes necessary for forming a package board are now complete. Material and method for forming the solder mask 310 are the same as in the first embodiment. Similarly, material and method for forming the electroplated layers 314a and 314b are also the same as in the first embodiment.

33. As shown in FIG. 3F, after the packaging board is made, a silicon chip 316 is placed on top of the solder mask 310 and fixed in position using material such as insulating plastic, silver paste or bonding tape. The silicon chip 316 and the conductive line layers 304c are electrically connected by performing a wire-bonding operation. Conductive wires 318 are used to link up bonding pads (not shown in the figure) on the silicon chip 316 with the electroplated bond pads 314a. The conductive wires 318, for example, are made of gold, aluminum or copper. A molding step is carried out using a packaging material 320 to enclose the silicon chip 316, the conductive wires 318, a portion of the soldering mask 310, the conductive line layers 304c and the substrate board 300a. The packaging material 320 includes resin and epoxy resin. Soldering material 322, including solder or copper balls, can also be placed over the electroplated layer 314b of the ball grid pads to form a ball grid array. The soldering material serves as a medium for connecting the chip package to a printed circuit board.

34. In summary, the invention uses hard resin to form the single-sided substrate board of a low pin count electronic package. The package board is formed in such a way that the internal circuit path is shortened and so RC delay is greatly reduced. Hence, the package is able to work faster and more efficiently. Moreover, it costs less to produce such an IC package.

35. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming package board, comprising the steps of:
providing a substrate board;
forming a plurality of through vias in the substrate board;
forming patterned conductive line layers on the substrate board such that a plurality of ball grid pad regions on the conductive line layers is patterned by the vias; and
forming a soldering mask that covers a portion of the conductive line layers while exposing a plurality of bonding pad regions.

2. The method of claim 1, wherein the substrate board has an electroplated layer thereon.

3. The method of claim 1, wherein the step of forming the through vias includes using a mechanical punching method.

4. The method of claim 2, wherein after the formation of vias but before the formation of conductive line layers, further includes removing the electroplated layer.

5. The method of claim 4, wherein the step of removing the electroplated layer includes using a wet etching method.

6. The method of claim 1, wherein the step of forming conductive line layers on the substrate board includes the sub-steps of:
forming a glue layer over the substrate board;
attaching a conductive layer onto the glue layer; and
patterning the conductive layer to form the patterned conductive line layers.

7. The method of claim 1, wherein the step of forming the conductive line layers includes using a wet etching method.

8. The method of claim 1, wherein the step of forming the soldering mask includes using a roller coating method.

9. The method of claim 1, wherein the step of forming the soldering mask includes using a curtain coating method.

10. The method of claim 1, wherein the step of forming the soldering mask includes using a screen printing method.

11. The method of claim 1, wherein the step of forming the soldering mask includes using a dry film method.

12. The method of claim 1, wherein after the formation of the soldering mask, further includes forming an electroplated bond pad layer over the bonding pad region.

13. A method of forming package board, comprising the steps of:
providing a substrate board having a first electroplated layer over a first surface of the substrate board and a second electroplated layer over a second surface of the substrate board;
patterning the first electroplated layer and the second electroplated layer to form conductive line layers and an intermediate electroplated layer, respectively, so that a portion of the substrate board is exposed, and the intermediate electroplated layer is used to pattern out ball grid pad regions;
removing some substrate board material within the ball grid pad regions to form a plurality of ball grid pad openings that expose a portion of the conductive line layer;
removing the intermediate electroplated layer to expose the second surface of the substrate board; and
forming a soldering mask that covers a portion of the conductive line layers while exposing a plurality of bonding pad regions.

14. The method of claim 13, wherein the step of forming the conductive line layers and the intermediate electroplated layer includes conducting photolithographic and etching operations.

15. The method of claim 13, wherein the step of forming the ball grid pad openings includes using laser ablation.

16. The method of claim 13, wherein the step of removing the intermediate electroplated layer includes wet etching.

17. The method of claim 13, wherein the step of forming the soldering mask includes roller coating.

18. The method of claim 13, wherein the step of forming the soldering mask includes curtain coating.

19. The method of claim 13, wherein the step of forming the soldering mask includes screen printing.

20. The method of claim 13, wherein the step of forming the soldering mask includes using dry film.

21. The method of claim 13, wherein after the formation of the soldering mask, further includes forming an electroplated bond pad layer over the bonding pad region.

22. A package board structure, comprising:
a substrate board having a plurality of through vias, wherein the substrate board is made using glass epoxy resin or bismaleimide-triazine (BT);
a patterned conductive line layer on the substrate board that also covers the through vias; and
a soldering mask covering a portion of the conductive line layer and exposing a bonding pad region of the conductive line layer.

23. The structure of claim 22, wherein the material for forming the conductive line layer includes copper.

24. The structure of claim 22, wherein the material for forming the soldering mask includes an ultraviolet-sensitive compound.

25. The structure of claim 22, wherein the material for forming the soldering mask includes a bake-hardened compound.

26. The structure of claim 22, wherein the structure further includes a glue layer between the substrate board and the conductive line layer.

27. The structure of claim 22, wherein the bonding pad region has an electroplated layer above the bonding pad region.

28. The structure of claim 27, wherein the metal for forming the electroplated layer is selected from a group that includes gold, silver, palladium, nickel and a combination of the above listed metals.

29. A semiconductor package, comprising:
a substrate board having a plurality of through vias, wherein the substrate board is made using glass epoxy resin or bismaleimide-triazine (BT);
a patterned conductive line layer on the substrate board that also covers the through vias;
a soldering mask covering a portion of the conductive line layer and exposing a bonding pad region of the conductive line layer;
a silicon chip fixed onto the surface of the soldering mask and electrically connected to the bonding pads through conductive wires; and
an insulation material that encloses the silicon chip, the conductive wires, the soldering mask, the conductive line layer and a portion of the substrate board.

30. The package of claim 29, wherein the material for forming the conductive line layer includes copper.

31. The package of claim 29, wherein the material for forming the soldering mask includes an ultraviolet-sensitive compound.

32. The package of claim 29, wherein the material for forming the soldering mask includes a bake-hardened compound.

33. The package of claim 29, wherein the metal for forming the conductive wires is selected from a group that includes gold, aluminum and copper.

34. The package of claim 29, wherein the insulation material includes resin.

35. The package of claim 29, wherein the insulation material includes epoxy resin.

36. The package of claim 29, wherein the package further includes a plurality of solder balls inserted inside the through vias electrically connected with the conductive line layer.

37. The package of claim 29, wherein the package further includes a plurality of copper balls inserted inside the through vias electrically connected with the conductive line layer.

38. The package of claim 29, wherein the package further includes a glue layer between the conductive line layer and the substrate board.

39. The package of claim 29, wherein the bonding pad region has an electroplated layer above the bonding pad region.

40. The structure of claim 39, wherein the metal for forming the electroplated layer is selected from a group that includes gold, silver, palladium, nickel and a combination of the above listed metals.
